(19) United States
(12) Patent Application Publication
(10) Pub. No.: US 2015/0029656 A1
(43) Pub. Date: Jan. 29, 2015

(54) MOUNTING APPARATUS FOR DATA STORAGE DEVICE

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: WEN-HU LU, Shenzhen (CN); LUNG-SHENG TSAI, New Taipei (TW)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/261,694

(22) Filed: Apr. 25, 2014

(30) Foreign Application Priority Data
Jul. 25, 2013 (CN) 2013103157823

(51) Int. Cl. G06F 1/18; H05K 7/14

(52) U.S. Cl. CPC G06F 1/187; H05K 7/1488; H05K 7/1427; H05K 7/1401
USPC 361/679.39; 361/679.33; 312/223.2; 248/220.21; 248/560

(57) ABSTRACT

A mounting apparatus for securing a data storage device includes a mounting tray, which includes a bottom wall, two sidewalls perpendicularly extending from the bottom wall, a positioning protrusion extending from the bottom wall, and a latching protrusion extending from each sidewall. The latching protrusions are configured for being received in latching holes defined in the data storage device. Each sidewall is elastically deformable. A distance between the two sidewalls is substantially equal to a width of the data storage device. An extending direction of the positioning protrusion is substantially perpendicular to an extending direction of the latching protrusion. An electronic device with the mounting apparatus is further disclosed.

### FIELD

Embodiments of the present disclosure relate to electronic devices, and particularly to an electronic device with a mounting apparatus for mounting a data storage device.

### BACKGROUND

Data storage devices are used for storing data in mounting apparatuses, such as computers and servers. Each data storage device is generally mounted in a bracket, and then the bracket is mounted in a computer enclosure by screws, which requires a screw driver to secure the screws to the bracket.

### BRIEF DESCRIPTION OF THE DRAWINGS

Many aspects of the embodiments herein can be better understood with reference to the following drawings. The components in the drawings are not necessarily drawn to scale, the emphasis instead being placed upon clearly illustrating the principles of the embodiments. Like reference numerals designate corresponding parts throughout the several views of the drawings.

FIG. 1 is an exploded, isometric view of one embodiment of an electronic device with a mounting apparatus and two data storage devices.

FIG. 2 is an isometric view of a mounting tray of the electronic device of FIG. 1.

FIG. 3 is an enlarged view of a circled portion III of FIG. 1.

FIG. 4 is an enlarged view of a circled portion IV of FIG. 1.

FIG. 5 is an assembled, isometric view of the electronic device of FIG. 1.

FIG. 6 is a cross-sectional view of the electronic device of FIG. 1, taken along line VI-VI.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

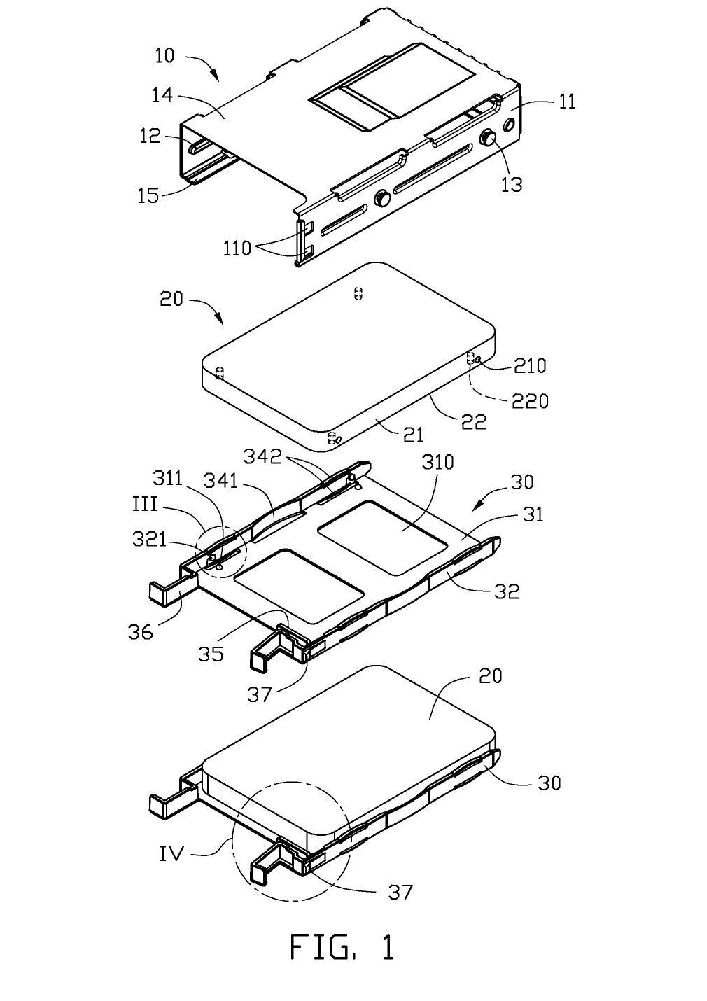

FIG. 1 illustrates one embodiment of an electronic device with a mounting apparatus. The mounting apparatus is configured for securing at least one data storage device 20 (two data storage devices 20 are shown) and includes a cage 10 and at least one mounting tray 30. In one embodiment, the data storage device 20 is a hard disk drive.

The cage 10 includes a top plate 14 and two side plates 11 substantially perpendicularly extending from opposite edges of the top plate 14. A flange 15 substantially perpendicularly extends inward from a bottom edge of each side plate 11. Two installation members 13 are located on each side plate 11 for securing the cage 10 to an electronic device (not shown). A guiding rail 12 protrudes from an inner surface of each side plate 11. In one embodiment, the guiding rail 12 is substantially parallel to the top plate 14 and located along a substantially central line of the side plate 11. One of the side plates 11 defines two mounting holes 110 in a line substantially perpendicular to the top plate 14. The two mounting holes 110 are located at opposite sides of the guiding rail 12.

The data storage device 20 includes a bottom surface 22 and two side surfaces 21 perpendicular to the bottom surface 22. Each of four corner portions of the bottom surface 22 defines a positioning hole 220. Each side surface 21 defines two latching holes 210. An extending direction of the positioning holes 220 is substantially perpendicular to an extending direction of the latching holes 210.

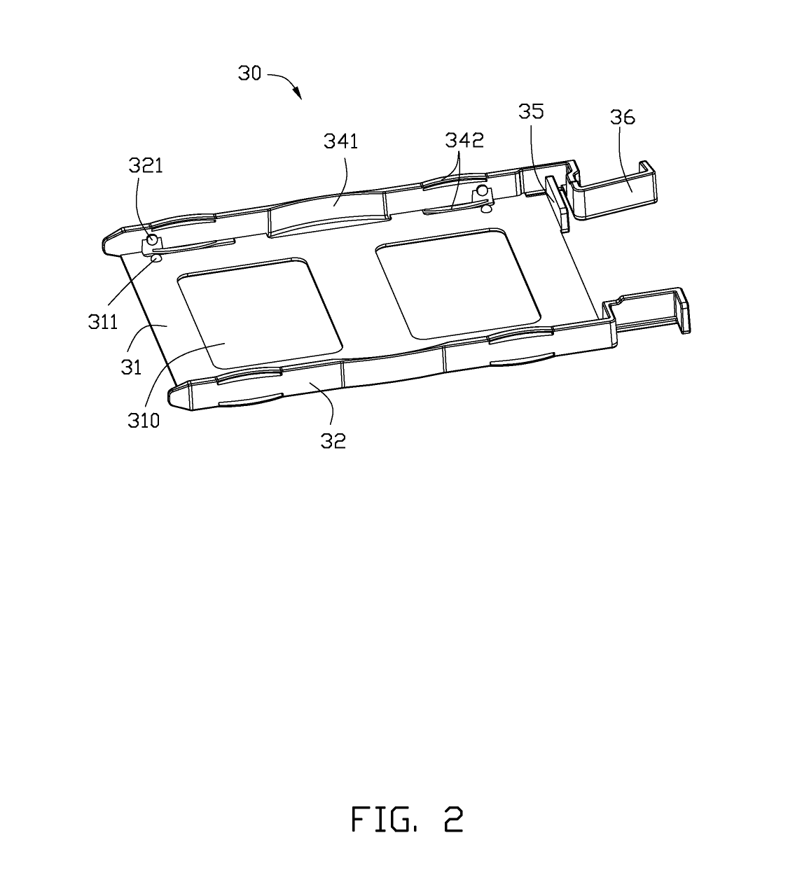

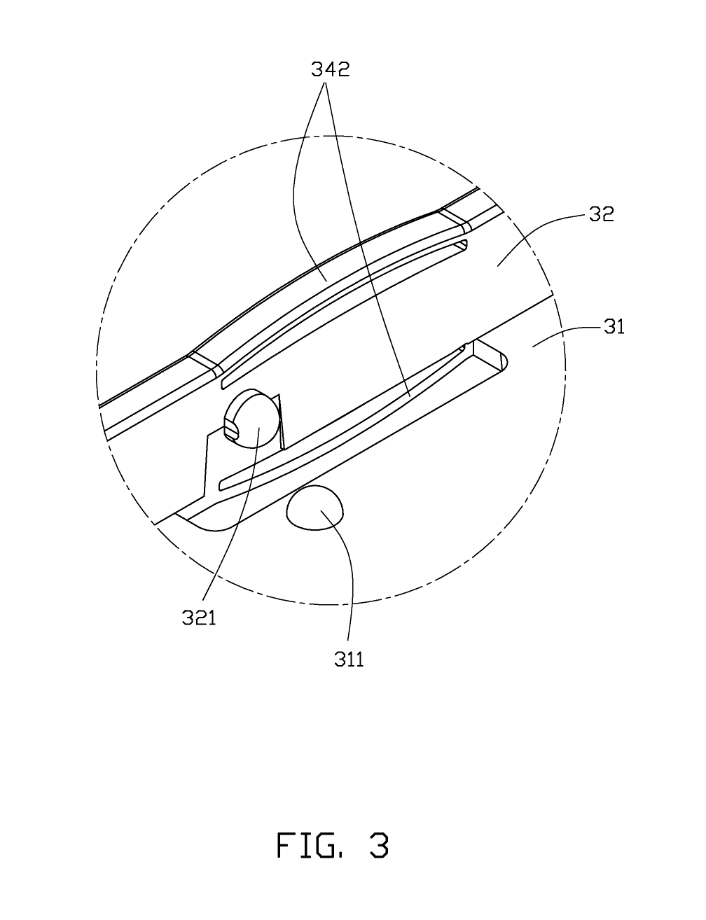

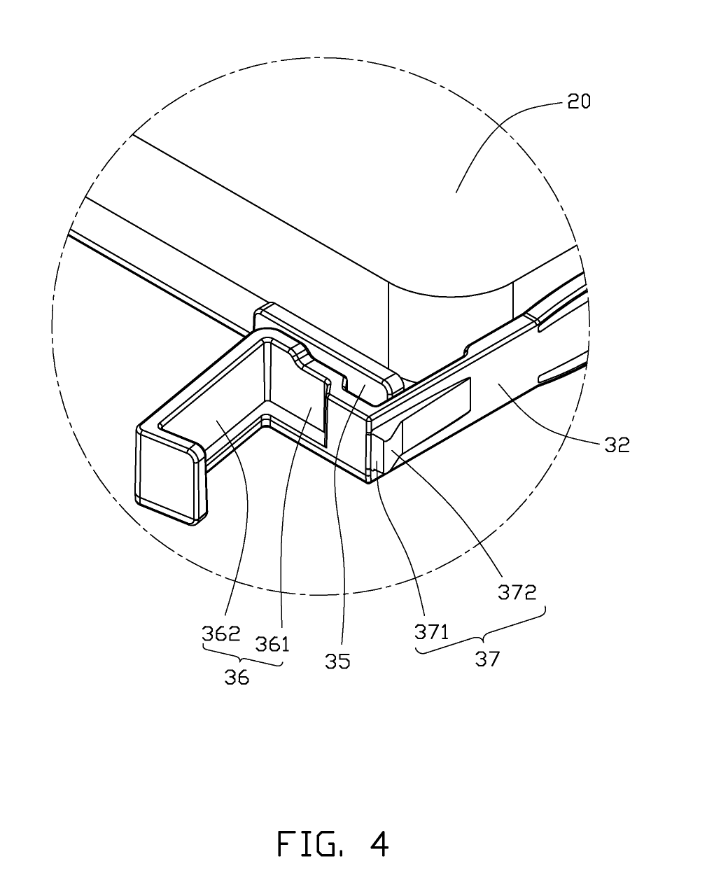

FIGS. 2-4 illustrate that the mounting tray 30 includes a bottom wall 31 and two sidewalls 32 substantially perpendicularly extending from the bottom wall 31. The bottom wall 31 defines two ventilation holes 310. Positioning protrusions 311 extend from the bottom wall 31 and correspond to the positioning holes 220. Latching protrusions 321 extend from each sidewall 32 and correspond to the latching holes 210. In one embodiment, the positioning protrusions 311 and the latching protrusions 321 are semispherical. A diameter of the positioning protrusion 311 is substantially equal to a diameter of the positioning hole 220. An extending direction of the positioning protrusion 311 is substantially perpendicular to an extending direction of the latching protrusion 321. An operation portion 36 extends from a front edge of each sidewall 32. The operation portion 36 includes a connecting piece 361 connected to the sidewall 32, and an operation piece 362 extending from the connecting piece 361. In one embodiment, the operation portion 36 is substantially “U” shaped, and the operation piece 362 is substantially “L” shaped. A locking portion 37 extends outward from one of the sidewalls 32 adjacent to the connecting piece 361. The locking portion 37 includes a locking plane 371 extending substantially perpendicularly from the sidewall 32, and a guiding plane 372 slantingly connected to the locking plane 371 and the sidewall 32. The mounting tray 30 further includes a limiting piece 35 extending from the bottom wall 31, a first shock absorbing portion 341 extending outwards from each sidewall 32, and two second shock absorbing portions 342 extending from each sidewall 32. Each second shock absorbing portion 342 includes two curved ribs extending from opposite edges of the sidewall 32. An extending direction of the first shock absorbing portion 341 is substantially perpendicular to each second shock absorbing portion 342. The first shock absorbing portion 341 is located between the two second shock absorbing portions 342. The limiting piece 35 is substantially perpendicular to the sidewall 32 and adjacent to the locking portion 37. In one embodiment, the mounting tray 30 is made of plastic and elastically deformable.

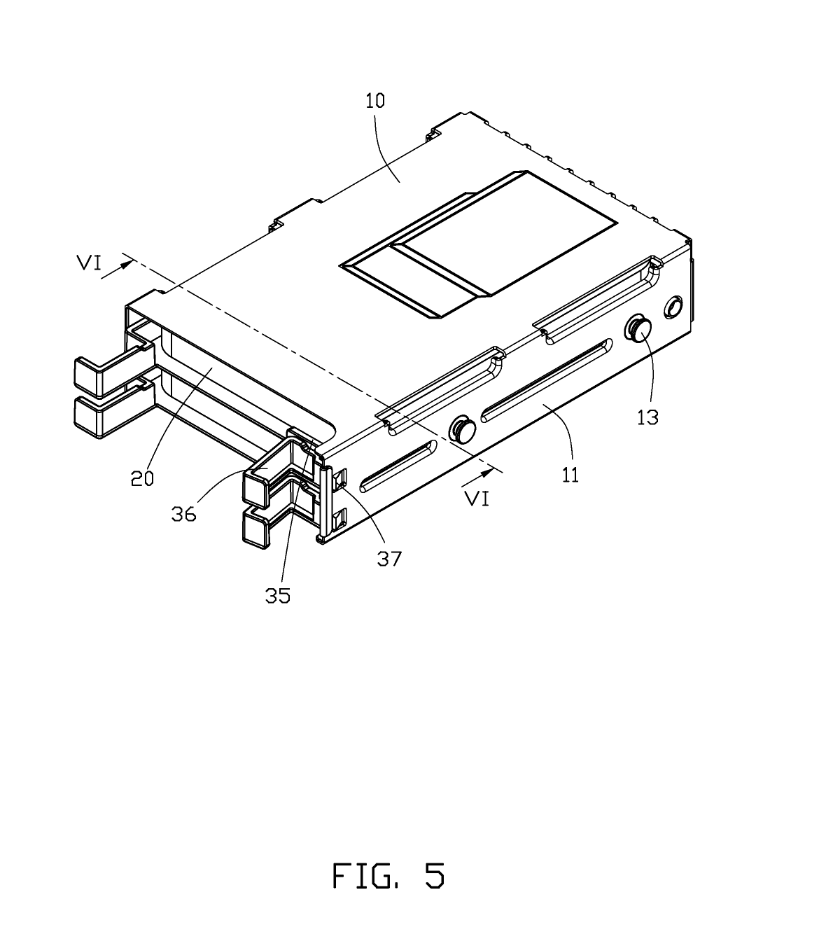

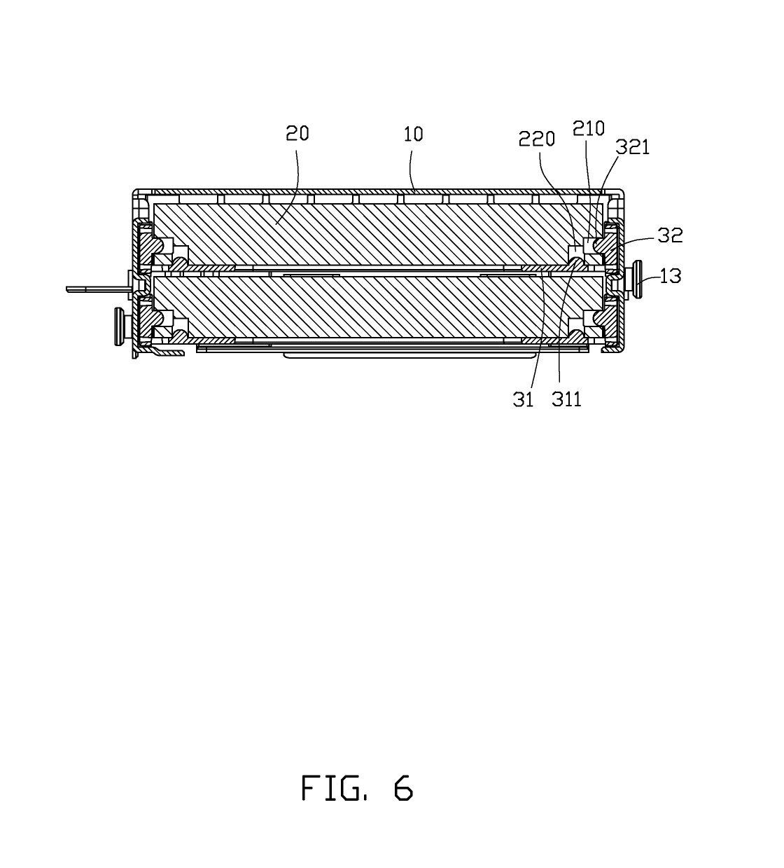

FIGS. 5-6 illustrate that in assembly, the data storage device 20 is placed on the bottom wall 31 of the mounting tray 30, such that the positioning protrusions 311 are received in the corresponding positioning holes 220. Because the sidewalls 32 are resilient, the latching protrusions 321 are received in the latching holes 210. In this position, the bottom surface 22 abuts against the bottom wall 31. Thus, the data storage device 20 is secured to the mounting tray 30. A gap is defined between the first shock absorbing portion 341 and the data storage device 20.

The mounting tray 30 is placed between the flanges 15 and the guiding rails 12, and then moved along the guiding rails 12. The corresponding side plate 11 presses against the guiding plane 372 of the locking portion 37, thereby pressing the corresponding sidewall 32 inward. When the locking portion 37 is aligned with the mounting hole 110, the sidewall 32 rebounds to extend the locking portion 37 through the mounting hole with the locking plane 371 abutting an edge of the mounting hole 110. Thus, the mounting tray 30 is secured to the cage 10. The first shock absorbing portions 341 are pressed against the side plates 11 to prevent the data storage device 20 from being shock.

In disassembly, the two operation pieces 362 are moved toward each other to elastically deform the two sidewalls 32 inward via the connecting pieces 361. When the corresponding sidewall 32 abuts the limiting piece 35, the locking portion 37 can be disengaged from the mounting hole 110. Thus, the mounting tray 30 can be removed from the cage 10. The sidewalls 32 are pulled outwards slightly, causing the latching protrusions 321 to be removed from the latching holes 210. Thus, the data storage device 20 can be removed from the mounting tray 30.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and the arrangement of parts within the principles of the disclosure. Embodiments described herein are examples, and are not intended to limit the following claims.

What is claimed is:

1. A mounting apparatus for securing a data storage device, the mounting apparatus comprising:
a mounting tray comprising a bottom wall and two sidewalls perpendicularly extending from the bottom wall;
a positioning protrusion extending from the bottom wall and configured for engaging in a positioning hole defined in the data storage device; and
a latching protrusion extending from each sidewall and configured for engaging in a latching hole defined in the data storage device;
wherein each sidewall is elastically deformable; a distance between the two sidewalls is substantially equal to a width of the data storage device; and an extending direction of the positioning protrusion is substantially perpendicular to an extending direction of the latching protrusion.

2. The mounting apparatus of claim 1, further comprising a cage, wherein the mounting tray is slidably mounted to the cage.

3. The mounting apparatus of claim 2, wherein the cage defines a mounting hole, the mounting tray further comprises a locking portion extending from one of the two sidewalls, and the locking portion is engaged in the mounting hole, preventing the mounting tray from being slid relative to the cage.

4. The mounting apparatus of claim 3, wherein the mounting tray further comprises an operation portion connected to each sidewall, and the operation portion is operable to elastically deform the sidewalls, causing the locking portion to be disengaged from the mounting hole.

5. The mounting apparatus of claim 4, wherein the mounting tray further comprises a limiting piece extending from the bottom wall, a gap is defined between the limiting piece and the one of the two sidewalls, and the limiting pieces abuts the one of the two sidewalls when the sidewalls are elastically deformed.

6. The mounting apparatus of claim 5, wherein the limiting piece is substantially perpendicular to each sidewall and the bottom wall.

7. The mounting apparatus of claim 5, wherein the operation portion comprises a connecting piece extending from an edge of each sidewall and an operation piece extending from the connecting piece, the connecting piece is substantially parallel to the limiting piece, and the operation piece is substantially an “L” shaped.

8. The mounting apparatus of claim 3, wherein the locking portion comprises a locking plane perpendicularly extending from the one of the two sidewalls and a guiding plane slantingly connected to the locking plane and the one of the two sidewalls, and the locking plane is engaged with an edge of the mounting hole.

9. The mounting apparatus of claim 1, wherein the mounting tray further comprises a shock absorbing portion protruding outwards from each sidewall.

10. The mounting apparatus of claim 1, wherein each of the positioning protrusion and the latching protrusion is semicircular.

11. An electronic device, comprising:
a data storage device comprising a bottom surface and a side surface, the bottom surface defining a positioning hole, and the side surface defining a latching hole;
a mounting tray comprising a bottom wall and two sidewalls perpendicularly extending from the bottom wall;
a positioning protrusion extending from the bottom wall and engaged in the positioning hole; and
a latching protrusion extending from each sidewall and engaged in the latching hole;
wherein each sidewall is elastically deformable; a distance between the two sidewalls is substantially equal to a width of the data storage device; an extending direction of the positioning hole is substantially perpendicular to an extending direction of the latching hole; and an extending direction of the positioning protrusion is substantially perpendicular to an extending direction of the latching protrusion.

12. The mounting apparatus of claim 11, further comprising a cage, wherein the mounting tray is slidably mounted to the cage.

13. The mounting apparatus of claim 12, wherein the cage defines a mounting hole, the mounting tray further comprises a locking portion extending from one of the two sidewalls, and the locking portion is engaged in the mounting hole, preventing the mounting tray from being slid relative to the cage.

14. The mounting apparatus of claim 13, wherein the mounting tray further comprises an operation portion connected to each sidewall, and the operation portion is operable to elastically deform the sidewalls, causing the locking portion to be disengaged from the mounting hole.

15. The mounting apparatus of claim 14, wherein the mounting tray further comprises a limiting piece extending from the bottom wall, a gap is defined between the limiting piece and the one of the two sidewalls, and the limiting pieces abuts the one of the two sidewalls when the sidewalls are elastically deformed.

16. The mounting apparatus of claim 15, wherein the limiting piece is substantially perpendicular to each sidewall and the bottom wall.

17. The mounting apparatus of claim 15, wherein the operation portion comprises a connecting piece extending from an edge of each sidewall and an operation piece extending from the connecting piece, the connecting piece is substantially parallel to the limiting piece, and the operation piece is substantially an “L” shaped.

18. The mounting apparatus of claim 13, wherein the locking portion comprises a locking plane perpendicularly extending from the one of the two sidewalls and a guiding plane slantingly connected to the locking plane and the one of the two sidewalls, and the locking plane is engaged with an edge of the mounting hole.

19. The mounting apparatus of claim 11, wherein the mounting tray further comprises a shock absorbing portion protruding outwards from each sidewall.

20. The mounting apparatus of claim 11, wherein each of the positioning protrusion and the latching protrusion is semicircular.
